(19) United States
(12) Patent Application Publication
(10) Pub. No.: US 2016/0248400 A1
(43) Pub. Date: Aug. 25, 2016

(54) APPARATUS AND METHODS FOR RADIO FREQUENCY SWITCHING

(71) Applicant: Analog Devices, Inc., Norwood, MA (US)

(72) Inventor: Benjamin P. Walker, Cambridge, MA (US)

(21) Appl. No.: 14/630,985

(22) Filed: Feb. 25, 2015

(51) Int. Cl. H03H 11/24; H03K 17/687; H04W 72/04

(52) U.S. Cl. CPC H03H 11/245; H04W 72/0406; H03K 17/6871

(57) ABSTRACT

Provided herein are apparatus and methods for radio frequency (RF) switching. In certain configurations, an RF switching circuit includes two or more FETs electrically connected in series between an input terminal and an output terminal, with the two or more FETs in the series connected via one or more intermediate nodes. The RF switching circuit receives a first switch control signal that can be used to control the DC bias voltages of the gates of the two or more FETs, and a second switch control signal that can be used to control the DC bias voltages of the one or more intermediate nodes.

### BACKGROUND

1. Field

Embodiments of the invention relate to electronic systems, and more particularly, to radio frequency (RF) switches.

2. Description of the Related Technology

Radio frequency (RF) systems frequently include RF switches to electrically couple or decouple circuits and/or nodes within an RF system.

In one example, an RF system, such as a mobile device or base station, can include a digital step attenuator (DSA) implemented using RF switches. Additionally, the RF switches can be used to control the amount of attenuation provided by the DSA.

In another example, an RF system can include an antenna switch module (ASM) implemented using RF switches, and the ASM can be used to electrically connect an antenna to a particular transmit or receive path of the RF system, thereby allowing multiple components to access the antenna.

### SUMMARY

In one aspect, a radio frequency (RF) system including a first RF switching circuit is provided. The first RF switching circuit includes a first terminal, a second terminal, a first control terminal configured to receive a first control signal, a second control terminal configured to receive a second control signal, and two of more field-effect transistors (FETs) electrically connected in series between the first terminal and the second terminal. The two or more FETs include a first FET including a source/drain electrically connected to the first terminal and a second FET including a source/drain electrically connected to the second terminal. A first intermediate node is disposed along a signal path between a drain/source of the first FET and a drain/source of the second FET. The first control signal is configured to control a DC bias voltage of a gate of the first FET and a DC bias voltage of a gate of the second FET, and the second control signal is configured to control a DC bias voltage of the first intermediate node.

In another aspect, a method of RF switching is provided. The method includes receiving a first control signal and a second control signal as inputs to an RF switching circuit that includes two or more field-effect transistors (FETs) electrically connected in series between a first terminal and a second terminal. The method further includes controlling a DC bias voltage of a gate of a first FET of the two or more FETs using the first control signal. The method further includes controlling a DC bias voltage of a gate of a second FET of the two or more FETs using the first control signal. A source/drain of the first FET is electrically connected to the first terminal, and a source/drain of the second FET is electrically connected to the second terminal. The method further includes controlling a DC bias voltage of a first intermediate node using the second control signal. The first intermediate node is disposed along a signal path between a drain/source of the first FET and a drain/source of the second FET.

In another aspect, a digital step attenuator is provided. The digital step attenuator includes an attenuation control circuit configured to generate a plurality of control signals including a first control signal and a second control signal. The digital step attenuator further includes a plurality of attenuation stages including a first attenuation stage. The first attenuation stage includes a first RF switching circuit. The first RF switching circuit includes a first terminal, a second terminal, a first control terminal configured to receive the first control signal, a second control terminal configured to receive the second control signal, and two of more field-effect transistors (FETs) electrically connected in series between the first terminal and the second terminal. The two or more FETs include a first FET including a source/drain electrically connected to the first terminal and a second FET including a source/drain electrically connected to the second terminal. A first intermediate node is disposed along a signal path between a drain/source of the first FET and a drain/source of the second FET. The first control signal is configured to control a DC bias voltage of a gate of the first FET and a DC bias voltage of a gate of the second FET. The second control signal is configured to control a DC bias voltage of the first intermediate node.

### BRIEF DESCRIPTION OF THE DRAWINGS

FIG. 1 is a schematic diagram of a radio frequency (RF) system that can include one or more RF switching circuits in accordance with the teachings herein.

FIG. 2A is a schematic diagram of a digital step attenuator (DSA) according to one embodiment.

FIG. 2B is a schematic diagram of an RF switching system according to one embodiment.

FIG. 2C is a schematic diagram of an RF switching system according to another embodiment.

FIG. 2D is a schematic diagram of an RF switching system according to another embodiment.

FIG. 2E is a schematic diagram of an RF switching system according to another embodiment.

FIG. 3A is a schematic diagram of an attenuator stage according to one embodiment.

FIG. 3B is a schematic diagram of an attenuator stage according to another embodiment.

FIG. 3C is a schematic diagram of an attenuator stage according to another embodiment.

FIG. 4A is a schematic diagram of an RF switching circuit according to one embodiment.

FIG. 4B is a schematic diagram of an RF switching circuit according to another embodiment.

FIG. 4C is a schematic diagram of an RF switching circuit according to another embodiment.

FIG. 4D is a schematic diagram of an RF switching circuit according to another embodiment.

FIG. 4E is a schematic diagram of an RF switching circuit according to another embodiment.

FIG. 4F is a schematic diagram of an RF switching circuit according to another embodiment.

### DETAILED DESCRIPTION OF EMBODIMENTS

The following detailed description of embodiments presents various descriptions of specific embodiments of the invention. However, the invention can be embodied in a multitude of different ways as defined and covered by the claims. In this description, reference is made to the drawings where like reference numerals may indicate identical or functionally similar elements.

Radio frequency (RF) switches can be implemented using field-effect transistors (FETs), such as metal oxide semiconductor field-effect transistors (MOSFETs). For example, an N-channel FET (NFET) can operate as an RF switch, and the gate of the NFET can be controlled by a gate control signal to turn on or off the RF switch. When the NFET operates in an ON state, the NFET provides a low-impedance path between its source and drain. Furthermore, when the NFET operates in an OFF state, the NFET operates in a cutoff region and provides high-impedance between its source and drain. The NFET can be operated in the OFF or OFF states by controlling the gate-to-source, gate-to-drain, and gate-to-backgate voltages of the NFET. As used herein, a backgate can also refer to a body or body terminal of a FET.

The particular voltages at the gate, backgate, drain, and source of a FET sufficient to turn the FET on or off can be dependent on a variety of factors. For example, the FET turn-on and turn-off voltage levels can be based on the FET's threshold voltage, which can vary with a process used to fabricate the FET.

A FET can be used to pass or block RF signals having time varying voltage amplitudes. On the other hand, a FET can receive a control signal that can have a substantially fixed voltage level when the FET operates in a particular state. For instance, in one example, a gate control signal can have a voltage about equal to a ground or power low supply voltage to turn off an FET and a voltage about equal to a power high supply voltage to turn on the FET. When the FET is used to pass or block an RF signal, changes in the RF signal's voltage amplitude can result in the FET's gate-to-source and/or drain-to-source voltages changing over time. Changes in the FET's gate-to-source, gate-to-drain, and gate-to-backgate voltages with time can cause undesirable behavior, such as a variation in the drain-to-source resistance of the FET and/or an unintended change from the OFF-state to an ON-state. Accordingly, such bias voltage variations can lead to distortion in the RF signal.

The ON-state and/or OFF-state performance of a FET can be degraded further by large RF signal swing. For example, when a FET is biased in the ON-state, a large RF signal swing can cause the FET's gate-to-source, gate-to-drain, or gate-to-backgate voltages to change over time, causing variations in the drain-to-source or channel resistance of the FET. Additionally, a large RF signal swing can cause a FET that is biased in the OFF-state to turn on during part of the RF signal cycle. In configurations with low DC bias voltages, such as input bias voltages of 0 V, it can be difficult to keep the FET turned off in the presence of large signal swings. For instance, when a FET is operated in the OFF state with source and gate DC voltages of about 0 V, an RF signal with an amplitude greater than the FET's threshold voltage may turn on the FET at certain time instances.

Accordingly, limitations in FET biasing can constrain the voltage range or signal swing of the RF signal with respect to the FET's gate voltage. However, such constraints may be unacceptable for certain applications and/or systems.

Provided herein are apparatus and methods for radio frequency (RF) switching. In certain configurations, an RF switching circuit includes two or more FETs electrically connected in series between an input terminal and an output terminal, with the two or more FETs in the series connected via one or more intermediate nodes. The RF switching circuit receives a first switch control signal that can be used to control the DC bias voltages of the gates of the two or more FETs, and a second switch control signal that can be used to control the DC bias voltages of the one or more intermediate nodes.

To turn on the RF switching circuit, the first and second switch control signals can control the FETs' gate-to-source, gate-to-drain, and gate-to-backgate voltages to provide a low impedance path between the input terminal and the output terminal. However, to turn off the RF switching circuit, the first and second switch controls signals can bias the FETs strongly off to enhance the RF switching circuit's linearity in the presence of large RF signal swing. For example, in a configuration using NFETs, the RF switching circuit can be turned off by controlling the first switch control signal to a ground or power low supply voltage and by controlling the second switching control signal to a power high supply voltage. Configuring the RF switching circuit in this manner can provide gate-to-source, gate-to-drain, and/or gate-to-backgate voltages that are highly negative in the switching circuit's OFF-state, thereby maintaining the FET in the OFF state throughout the RF signal cycle.

In certain configurations, the first and second control signals are provided to the FETs through resistors or other isolation circuitry. For example, in certain implementations, the RF switching circuit includes a first control terminal that receives the first control signal and a second control terminal that receives the second control signal. Additionally, the gate of each FET is electrically connected to the first control terminal through a gate biasing resistor, and each of the intermediate nodes is electrically connected to the second control terminal through a channel biasing resistor. By including the gate and channel biasing resistors, the FETs' bias voltages can dynamically track changes in the RF signal's voltage amplitude, thereby enhancing performance in the presence of RF signal swing. For example, a FET can include parasitic gate-to-drain and gate-to-source capacitors, which can operate to bootstrap the FET's gate in response to changes in the source and drain voltages. In certain configurations, one or more of the FETs include explicit gate-to-source and/or gate-to-drain capacitors to enhance bootstrapping.

The RF switching circuits herein can be used in a wide variety of applications. In one example, an RF switching circuit can be included in a digital step attenuator (DSA) stage to enhance the linearity of the DSA by operating as a shunt switch to an attenuation circuit when the DSA stage is activated and/or by operating as a bypass switch when the DSA stage is deactivated. In another example, an RF switching circuit is included in an antenna switch module.

In certain configurations, an RF switching circuit's input and output terminals can be operated at low DC bias voltages, such as DC bias voltages of ground or 0 V. Additionally, the second control signal can be used to control the one or more intermediate nodes to a relatively high voltage in the RF switching circuit's OFF-state, thereby maintain the RF switching circuit turned off across the RF signal cycle even when operating with 0 V DC bias voltages and large RF signal swings. By configuring an RF switching circuit in this manner, the RF switching circuit can be included in an RF system that operates using 0 V DC bias voltages without needing to include DC blocking capacitors at input and/or output terminals, which can degrade bandwidth.

The RF switching circuits herein can also enhance the linearity of a DSA or other RF system without needing to use charge pumps to generate FET gate voltages in the OFF-state. Charge pumps can be undesirable in certain applications, since charge pumps can occupy chip area, increase power consumption, and/or generate noise. For instance, clock signals used internally to control a charge pump can generate output frequency spurs that can mix with an RF signal propagating through an RF switching circuit, thereby generating out-of-band emissions and/or spurious noise.

The teachings herein can be used to enhance the performance of an RF system relative to a configuration using conventional switches. For example, the RF switching circuits herein can operate using RF signals having relatively large peak-to-peak voltage swings. Thus, the RF switching circuits can exhibit greater power handling and/or signal handling capabilities. Additionally, the RF switching circuits herein can have ON-state impedances and OFF-state impedances that have a smaller variation in the presence of RF signal swing. Thus, the RF switching circuits can operate to enhance linearity, to lower distortion, and/or to improve RF isolation.

The following description refers to RF systems and RF switching circuits. An RF system can include one or more RF switching circuits. An RF system can also include a control circuit that generates controls signals for controlling the RF switching circuits.

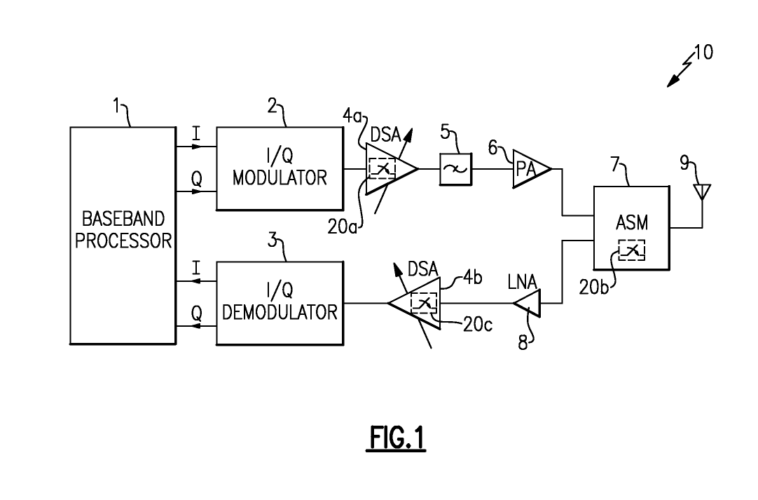

FIG. 1 is a schematic diagram of a radio frequency (RF) system 10 that can include one or more RF switching circuits in accordance with the teachings herein.

Although, the RF system 10 illustrates one example of an electronic system that can include RF switching circuits as described herein, RF switching circuits can be used in other configurations of electronic systems. Additionally, although a particular configuration of components is illustrated in FIG. 1, the RF system can be adapted and modified in a wide variety of ways. For example, the RF system 10 can include more or fewer receive and/or transmit paths. Additionally, the RF system 10 can be modified to include more or fewer components and/or a different arrangement of components, including, for example, a different arrangement of RF switching circuits.

In the illustrated configuration, the RF system 10 includes a baseband processor 1, an I/Q modulator 2, an I/Q demodulator 3, a first digital step attenuator 4a, a second digital step attenuator 4b, a filter 5, a power amplifier 6, an antenna switch module 7, a low noise amplifier 8, and an antenna 9.

As shown in FIG. 1, baseband processor 1 generates an in-phase (I) transmit signal and a quadrature-phase (Q) transmit signal, which are provided to the I/Q modulator 2. Additionally, the baseband processor 1 receives an I receive signal and a Q receive signal from the I/Q demodulator 3. The I and Q transmit signals correspond to signal components of a sinusoidal wave or transmit signal of a particular amplitude, frequency, and phase. For example, the I transmit signal and Q transmit signal represent an in-phase sinusoidal component and quadrature-phase sinusoidal component, respectively, and can be an equivalent representation of the transmit signal. Additionally, the I and Q receive signals correspond to signal components of a receive signal of a particular amplitude, frequency, and phase.

In certain implementations, the I transmit signal, the Q transmit signal, the I receive signal, and the Q receive signal can be digital signals. Additionally, the baseband processor 1 can include a digital signal processor, a microprocessor, or a combination thereof, used for processing the digital signals.

The I/Q modulator 2 receives the I and Q transmit signals from the baseband processor 1 and processes them to generate a modulated RF signal. In certain configurations, the I/Q modulator 2 can include DACs configured to convert the I and Q transmit signals into an analog format, mixers for upconverting the I and Q transmit signals to radio frequency, and a signal combiner for combining the upconverted I and Q signals into the modulated RF signal.

The first digital step attenuator 4a receives the modulated RF signal, and attenuates the modulated RF signal to generate an attenuated RF signal. The first digital step attenuator 4a can aid in obtaining a desired gain and/or power level associated with transmission. In the illustrated configuration, the first digital step attenuator 4a includes a first RF switching circuit 20a. The first digital step attenuator 4a illustrates one example of a circuit that can include one or more RF switching circuits in accordance with the teachings herein. For example, the first digital step attenuator 4a can include a cascade of attenuator stages, each of which can be bypassed using a RF switching circuit to aid in providing a digitally adjustable amount of attenuation.

The filter 5 receives the attenuated RF signal from the first digital step attenuator 4a, and provides a filtered RF signal to an input of the power amplifier 6. In certain configurations, the filter 5 can be a bandpass filter configured to provide band filtering. However, the filter 5 can be a low pass filter, a band pass filter, or a high pass filter, depending on the application.

The power amplifier 6 can amplify the filtered RF signal to generate an amplified RF signal, which is provided as to the antenna switch module 7. The antenna switch module 7 is further electrically connected to the antenna 9 and to an input of the low noise amplifier 8. The antenna switch module 7 can be used to selectively connect the antenna 9 to the output of the power amplifier 6 or to the input of the low noise amplifier 8.

In the illustrated configuration, the antenna switch module 7 includes a second RF switching circuit 20b. The antenna switch module 7 illustrates another example of a circuit that can include one or more RF switching circuits in accordance with the teachings here. For example, the antenna switch module 7 can include an RF switching circuit implemented as a single pole multi-throw switch. Although FIG. 1 illustrates a configuration in which the antenna switch module 7 operates as a double pole single throw switch, the antenna switch module 7 can be adapted to include additional poles and/or throws.

The LNA 8 receives an antenna receive signal from the antenna switch module 7, and generates an amplified antenna receive signal that is provided to the second digital step attenuator 4b. The second digital step attenuator 4b can attenuate the amplified antenna receive signal by a digitally-controllable amount of attenuation. As shown in FIG. 1, the second digital step attenuator 4b generates an attenuated receive signal, which is provided to the I/Q demodulator 3. Including the second digital step attenuator 4b can aid in providing the I/Q demodulator 3 with a signal that has a desired amplitude and/or power level. In the illustrated configuration, the second digital step attenuator 4b includes a third RF switching circuit 20c. The second digital step attenuator 4b illustrates another example of a circuit that can include one or more RF switching circuits in accordance with the teachings herein.

The I/Q demodulator 3 can be used to generate the I receive signal and the Q receive signal, as was described earlier. In certain configurations, the I/Q demodulator 3 can include a pair of mixers for mixing the attenuated receive signal with a pair of clock signals that are about ninety degrees out of phase. Additionally, the mixers can generate downconverted signals, which can be provided to ADCs used to generate the I and Q receive signals.

The RF system 10 can be used for transmitting and/or receiving RF signals using a variety of communication standards, including, for example, Global System for Mobile Communications (GSM), Code Division Multiple Access (CDMA), wideband CDMA (W-CDMA), Long Term Evolution (LTE), 3G, 3GPP, 4G, and/or Enhanced Data Rates for GSM Evolution (EDGE), as well as other proprietary and non-proprietary communications standards.

Providing an RF switch in a transmit or receive path of an RF system can impact the system's performance. For example, when an RF switch path is included in a transmit path of a transceiver, the RF switch can undesirably have insertion loss when operating in an ON or closed state. For example, the insertion loss can be associated with loss of signal power due to resistive losses. In the ON state, the RF switch may also exhibit non-linearity, which can degrade the quality of the signal. Furthermore, when the RF switch is operating in an OFF or opened state, the RF switch may nevertheless have a finite OFF state impedance that can impact RF isolation and/or linearity. For example, the RF switch can impact a wide variety of RF performance specifications, such as adjacent channel power ratio (ACPR). Additionally, when an RF switch is turned off but is positioned in a shunt configuration along an active signal path, the finite OFF state impedance of the RF switch can also lead to signal loss.

Accordingly, the ON state and OFF state performance of an RF switch can be important for a wide variety of reasons.

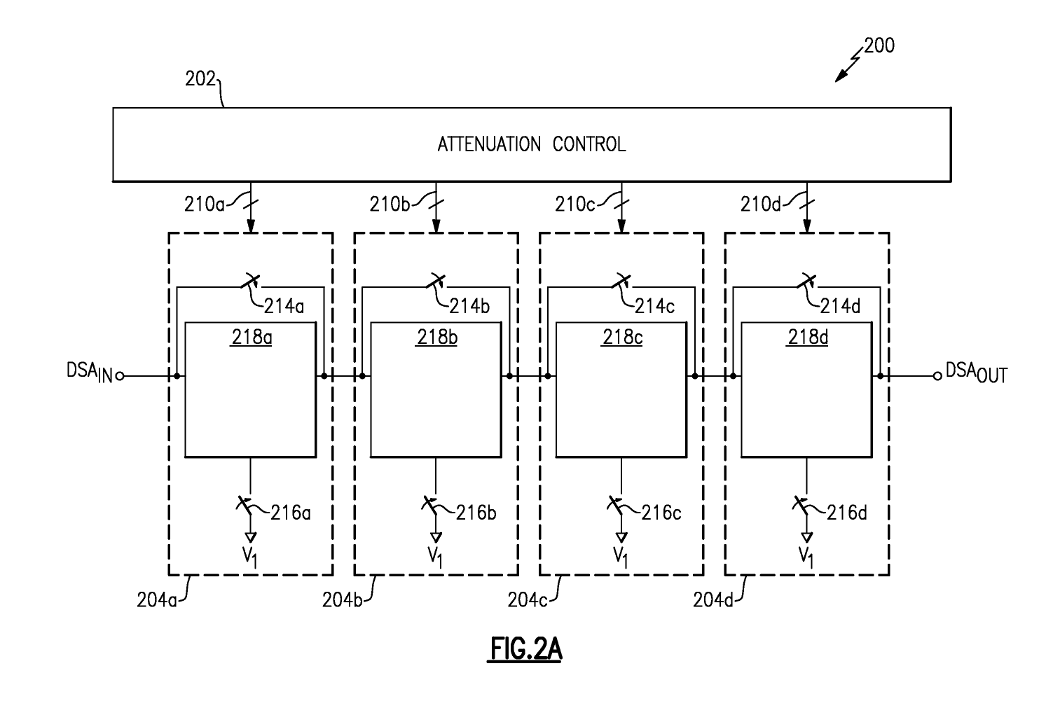

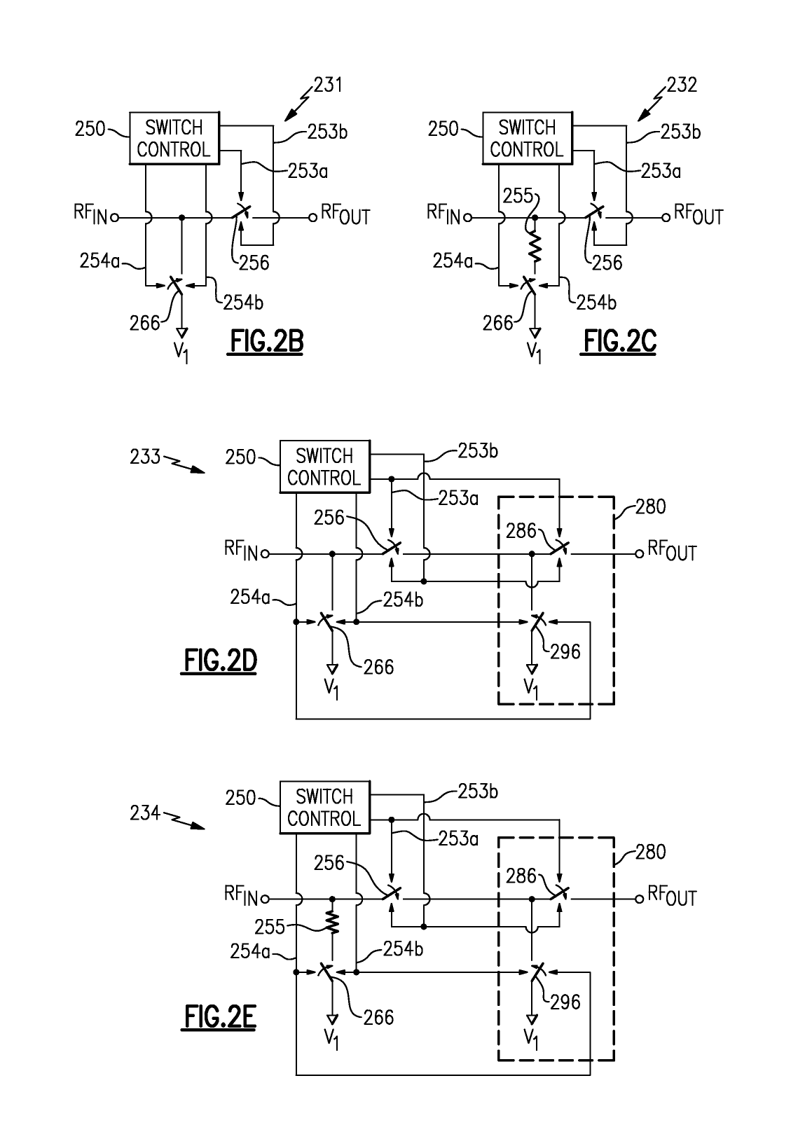

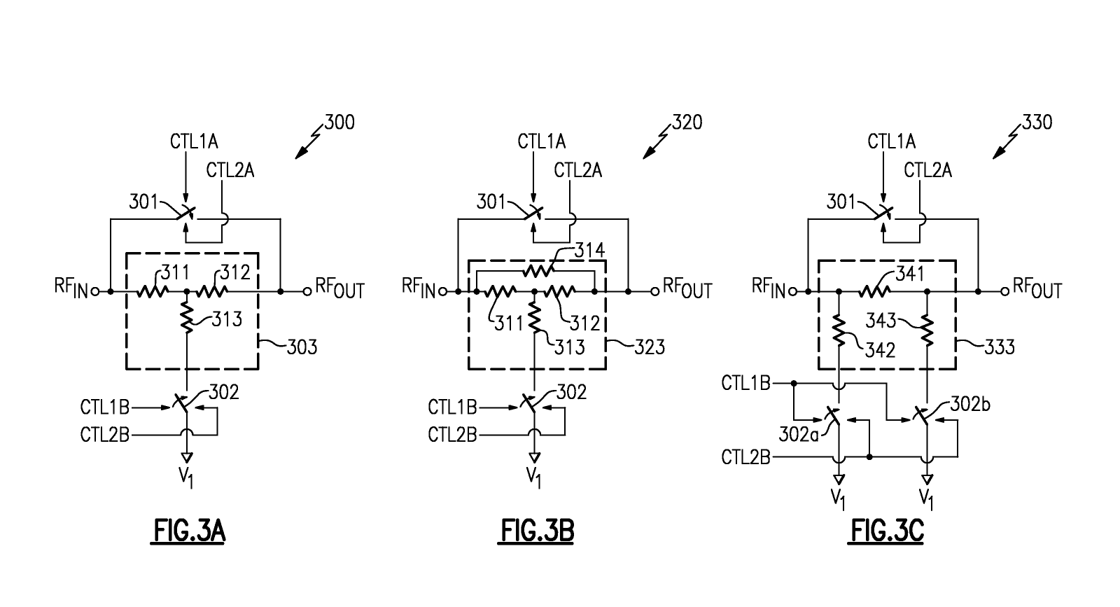

FIG. 2A is a schematic diagram of a digital step attenuator (DSA) 200 according to one embodiment. The DSA 200 includes an attenuation or switch control circuit 202, a first DSA stage or segment 204a, a second DSA stage 204b, a third DSA stage 204c, and a fourth DSA stage 204d. As shown in FIG. 2A, each of the first to fourth DSA stages 204a-204d includes an input and an output. Additionally, the DSA stages 204a-204d are arranged in series between a DSA input terminal DSA_{IN} and a DSA output terminal DSA_{OUT}.

Although FIG. 2A illustrates a configuration including four DSA stages, the teachings herein are applicable to configurations using more or fewer DSA stages.

The first DSA stage 204a includes a first bypass switching circuit 214a, a first shunt switching circuit 216a, and a first attenuation circuit 218a. The first attenuation circuit 218a includes a first terminal electrically connected to the input of the first DSA stage 204a, a second terminal electrically connected to the output of the first DSA stage 204a, and a third terminal electrically connected to a first or power low supply voltage V₁ through the first shunt switching circuit 112a. The first bypass switching circuit 214a is electrically connected between the input and output of the first DSA stage 204a, and can be used to selectively bypass the first attenuation circuit 218a.

The second DSA stage 204b includes a second bypass switching circuit 214b, a second shunt switching circuit 216b, and a second attenuation circuit 218b. The third DSA stage 204c includes a third bypass switching circuit 214c, a third shunt switching circuit 216c, and a third attenuation circuit 218c. The fourth DSA stage 204d includes a fourth bypass switching circuit 214d, a fourth shunt switching circuit 216d, and a fourth attenuation circuit 218d. Additional details of the second to fourth DSA stages 204b-204d can be similar to that of the first DSA stage 204a.

As shown in FIG. 2A, the attenuation control circuit 202 generates control signals for the RF switching circuits of the DSA stages 204a-204d. For example, the attenuation control circuit 202 generates a first plurality of controls signals 210a for the first DSA stage 204a, a second plurality of control signals 210b for the second DSA stage 204b, a third plurality of control signals 210c for the third DSA stage 204c, and a fourth plurality of control signals 210d for the fourth DSA stage 204d. For clarity of the figures, electrical connections between the control signals 210a-210d and individual switching circuits have been omitted from FIG. 2A.

The attenuation control circuit 200 can be used to control the amount of attenuation of the DSA 200 between the DSA input terminal DSA_{IN} and the DSA output terminal DSA_{OUT} using the control signals 210a-210d. In particular, the attenuation control circuit 200 can use the control signals 210a-210d to selectively turn on or off the bypass switching circuits 214a-214d and the shunt switching circuits 216a-216d to control the DSA's attenuation. In certain configurations, a bypass switching circuit and a shunt switching circuit of a particular DSA stage are controlled in a complementary manner. For example, when the stage's bypass switching circuit is turned on the stage's shunt switching circuit can be turned off, and vice-versa.

The DSA 200 of FIG. 2A illustrates one example of an RF system that can include one or more RF switching circuits in accordance with the teachings herein. For example, the bypass switching circuits 214a-214d and/or shunt switching circuits 216a-216d can be implemented using embodiments of RF switching circuits described herein.

FIG. 2B is a schematic diagram of an RF switching system 231 according to one embodiment. The RF switching system 231 includes a switch control circuit 250, a first or series switching circuit 256 and a second or shunt switching circuit 266. The series switching circuit 256 is electrically connected between an RF input RF_{IN} and an RF output RF_{OUT}, and the shunt switching circuit 266 is electrically connected between the RF input RF_{IN} and the power low supply voltage V₁.

As shown in FIG. 2B, the series switching circuit 256 receives a first series control signal 253a and a second series control signal 253b from the switch control circuit 250. The series switching circuit 256 can include two or more FETs electrically connected in series, with FETs in the series connected by one or more intermediate nodes. Additionally, the first series control signal 253a can be used to control the gate voltages of the FETs and the second series control signal 253b can be used to control the voltage of the one or more intermediate nodes. Similarly, the shunt switching circuit 266 receives a first shunt control signal 254a and a second shunt control signal 254b. The shunt switching circuit 266 can include two or more FETs electrically connected in series, and the first shunt control signal 254a can control the gate voltages of the two or more FETs and the second shunt control signal 254b can be used to control the voltages of intermediate nodes between the FETs.

The switch control circuit 250 can be used to control the states of operation of the series switching circuit 256 and the shunt switching circuit 266. For instance, in one embodiment the series control signals 253a-253b and the shunt control signals 254a-254b can be individually switched between a power low supply voltage and a power high supply voltage to control the states of the switching circuits 256, 266. In certain configurations, the switch control circuit 250 can control the states of the series switching circuit 256 and the shunt switching circuit 266 in a complementary manner. For instance when the series switching circuit 256 is turned on the shunt switching circuit 266 can be turned off, and vice-versa.

FIG. 2B illustrates another example of an RF system that can include one or more RF switching circuits in accordance with the teachings herein.

FIG. 2C is a schematic diagram of an RF switching system 232 according to another embodiment. The switching system 232 of FIG. 2C is similar to the switching system 231 of FIG. 2B, except that the switching system 232 further includes a resistor 255 electrically connected in series with the shunt switching circuit 266.

Including the resistor 255 can aid in operating the switching system 232 as an absorptive switch. For example, when the series switching circuit 256 is turned off and the shunt switching circuit 266 is turned on, the resistor 255 can be used to absorb an RF signal received at the RF input RF_{IN}. Including the resistor 255 can aid in preventing wave reflections and/or in meeting or surpassing performance specifications, such as voltage standing wave ration (VSWR) specifications. Additional details of the switching system 232 can be similar to those described earlier.

FIG. 2D is a schematic diagram of a switching system 233 according to another embodiment. The switching system 233 of FIG. 2D is similar to the switching system 231 of FIG. 2B, except that the switching system 233 further includes an isolation circuit 280 that includes a second series switching circuit 286 and a second shunt switching circuit 296.

As shown in FIG. 2D, the first series switching circuit 256 and the second series switching circuit 286 are electrically connected in series between the RF input RF_{IN} and the RF output RF_{OUT}, and are controlled using the first series control signal 253a and the second series control signal 253b from the switch control circuit 250. Additionally, the first shunt switching circuit 266 is electrically connected between an input terminal of the first series switching circuit 256 and the power low supply voltage V₁, and the second shunt switching circuit 296 is electrically connected between an input terminal of the second series switching circuit 286 and the power low supply voltage V₁. The first and second shunt switching circuits 266, 296 are controlled using the first shunt control signal 254a and the second shunt control signal 254b from the switch control circuit 250.

Including the isolation circuit 280 can enhance isolation relative to the configuration shown in FIG. 2B. However, including the isolation circuit 280 can also increase insertion loss and/or degrade linearity relative to the configuration shown in FIG. 2B. Additional details of the switching system 233 can be similar to those described earlier.

FIG. 2E is a schematic diagram of an RF switching system 234 according to another embodiment. The switching system 234 of FIG. 2E is similar to the switching system 233 of FIG. 2D, except that the switching system 234 further includes a resistor 255. In a manner similar to that described above with respect to the switching system 232 of FIG. 2C, the resistor 255 is electrically connected in series with the shunt switching circuit 266. As discussed in connection with FIG. 2C, including the resistor 255 aids in operating the switching system 234 as an absorptive switch to absorb an RF signal received at the RF input RF_{IN}. In addition, the switching system 234 of FIG. 2E allows the benefit of enhanced isolation in a similar manner to the switching system 233 of FIG. 2D.

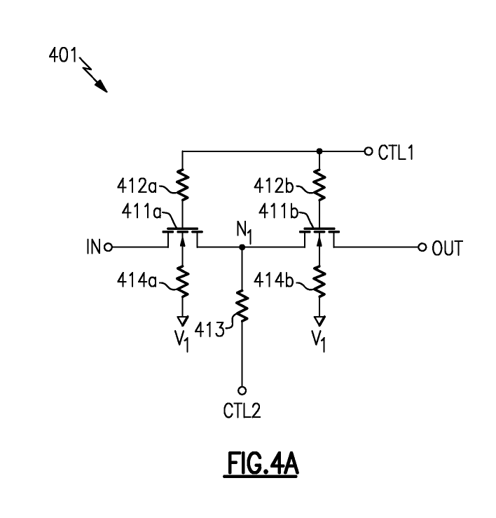

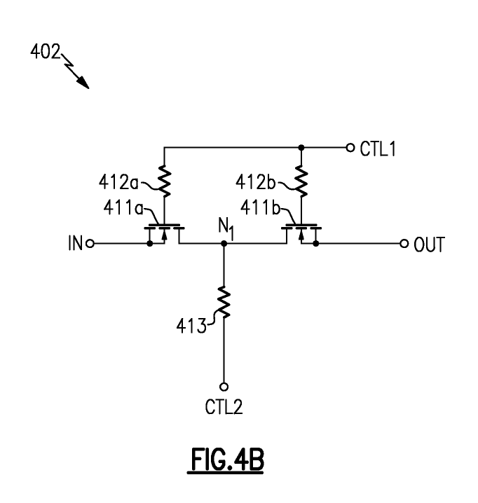

FIG. 3A is a schematic diagram of an attenuator stage 300 according to one embodiment. The attenuator stage 300 includes a bypass switching circuit 301, a shunt switching circuit 302, and an attenuation circuit 303. The attenuation circuit 303 includes a first terminal electrically connected to an RF input RF_{IN}, a second terminal electrically connected to an RF output RF_{OUT}, and a third terminal electrically connected to the power low supply voltage V₁ through the shunt switching circuit 302. The attenuation circuit 303 is configured as a T attenuator, and includes a first resistor 311, a second resistor 312, and a third resistor 313. As shown in FIG. 3A, the first resistor 311 includes a first end electrically connected to the attenuation circuit's first terminal and a second end electrically connected to a first end of the second resistor 312 and to a first end of the third resistor 313. Additionally, the second resistor 312 includes a second end electrically connected to the attenuation circuit's second terminal, and the third resistor 313 includes a second end electrically connected to the attenuation circuit's third terminal.

The bypass switching circuit 301 includes an input terminal electrically connected to the RF input RF_{IN}, an output terminal electrically connected to the RF output RF_{OUT}, a first control terminal that receives a first bypass control signal CTL1A, and a second control terminal that receives a second bypass control signal CTL2A. The shunt switching circuit 302 includes an input terminal electrically connected to the third terminal of the attenuation circuit 303, an output terminal electrically connected to the power low supply voltage V₁, a first control terminal that receives a first shunt control signal CTL1B, and a second control terminal that receives a second shunt control signal CTL2B.

The attenuator stage 300 illustrates one example of a DSA stage or segment that can include one or more RF switching circuits in accordance with the teachings herein. For example, the attenuator stage 300 can be included in the DSA 200 of FIG. 2A.

Additional details of the attenuator stage 300 can be similar to those described earlier.

FIG. 3B is a schematic diagram of an attenuator stage 320 according to one embodiment. The attenuator stage 320 of FIG. 3B is similar to the attenuator stage 300 of FIG. 3A, except that the attenuator stage 320 includes a different configuration of an attenuation circuit 323.

For example, in contrast to the attenuation circuit 303 of FIG. 3A which is implemented as a T attenuator, the attenuation circuit 323 of FIG. 3B is implemented as a bridged-T attenuator. In particular, the attenuation circuit 323 further includes a fourth resistor 314, which is electrically connected between the attenuation circuit's first and second terminals.

Additional details of the attenuator stage 320 can be similar to those described earlier.

FIG. 3C is a schematic diagram of an attenuator stage 330 according to another embodiment. The attenuator stage 330 of FIG. 3C is similar to the attenuator stage 300 of FIG. 3A, except that the attenuator stage 330 includes a different configuration of an attenuation circuit 333. Additionally, in contrast to the attenuator stage 300 of FIG. 3A which includes a single shunt switching circuit 302, the illustrated attenuator stage 330 includes first and second shunt switching circuits 302a, 302b.

The attenuation circuit 333 is implemented as a pi attenuator, and includes a first resistor 341 electrically connected between the RF input RF_{IN} and the RF output RF_{OUT}, a second resistor 342 electrically connected between the RF input RF_{IN} and an input terminal of the first shunt switching circuit 302a, and a third resistor 343 electrically connected between the RF output RF_{OUT} and an input terminal of the second shunt switching circuit 302b. As shown in FIG. 3C, the first and second shunt switching circuits 302a, 302b each include an output terminal electrically connected to the power low supply voltage V₁, a first control terminal that receives the first shunt control signal CTL1B, and a second control terminal that receives the second shunt control signal CTL2B.

Additional details of the attenuator stage 330 can be similar to those described earlier.

Although FIGS. 1-3C illustrated various electronic systems that can include RF switching circuits in accordance with the teachings herein, RF switching circuits can be used in other configuration of electronic systems.

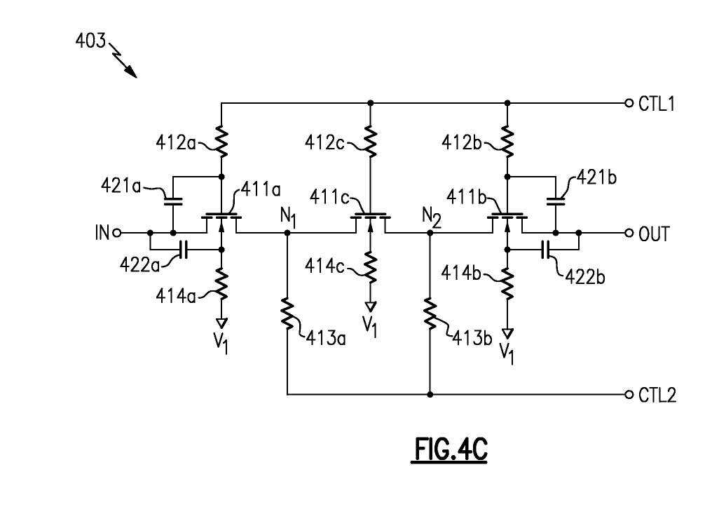

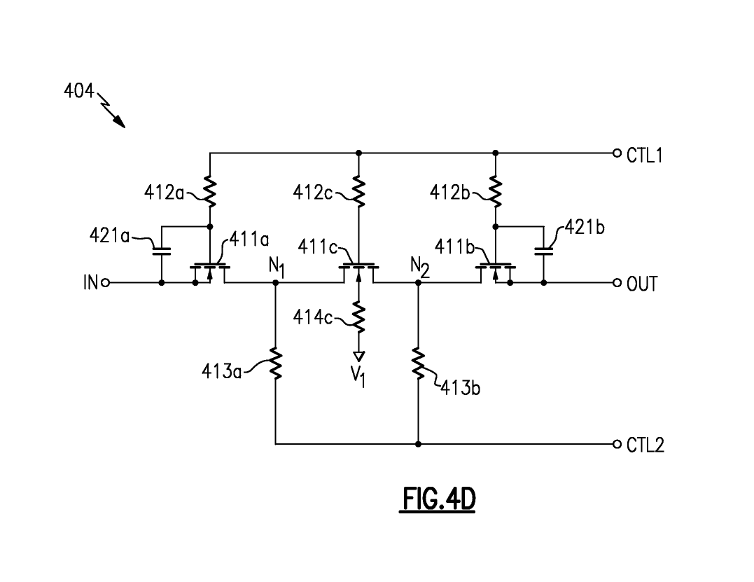

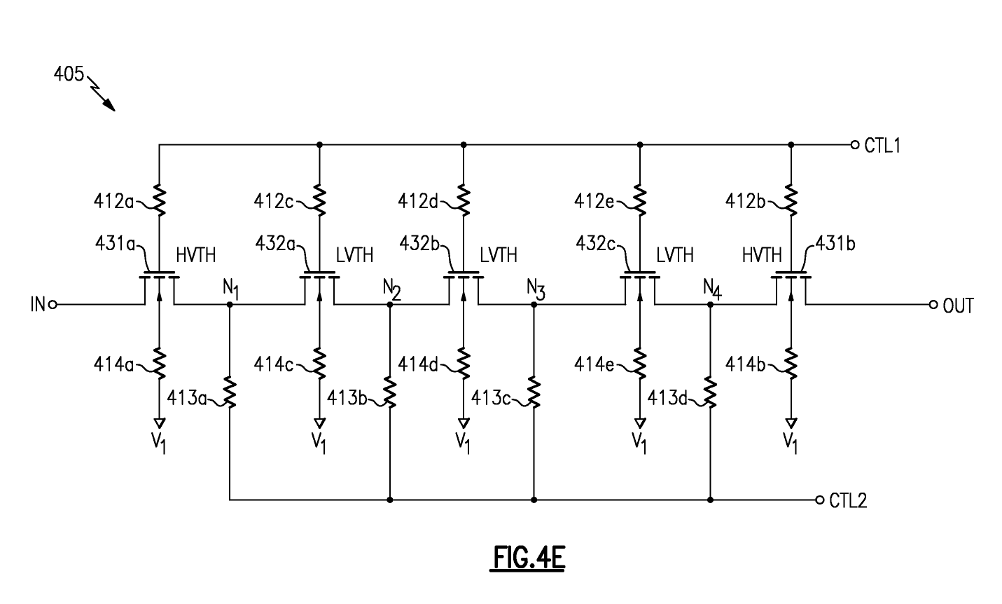

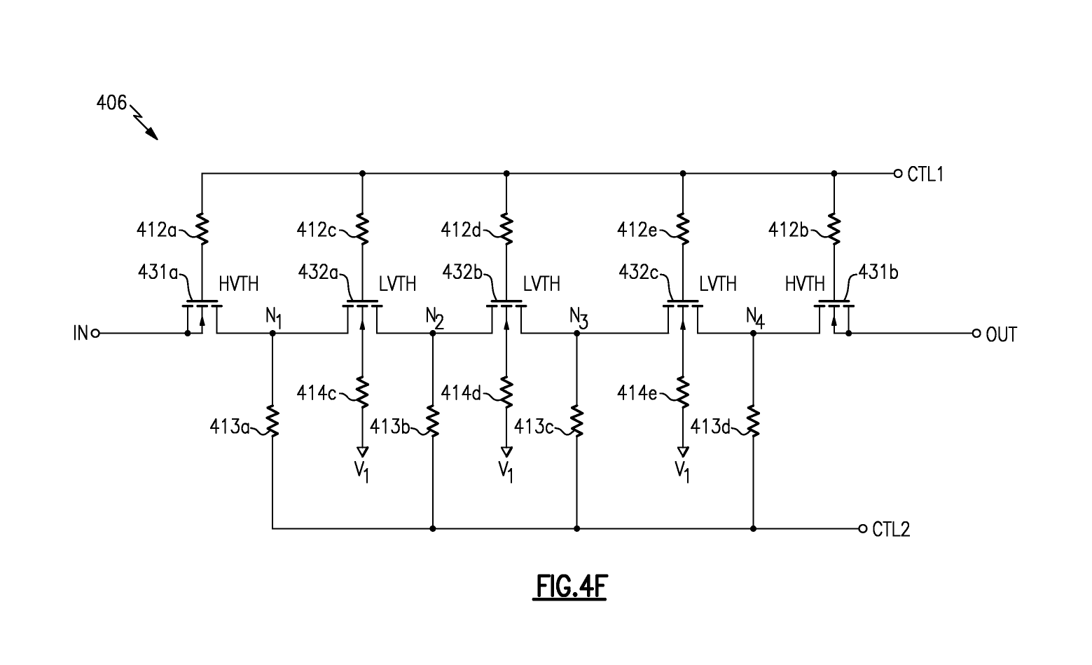

FIG. 4A is a schematic diagram of an RF switching circuit 401 according to one embodiment. The switching circuit 401 includes a first or RF input terminal IN, a second or RF output terminal OUT, a first control terminal CTL1, and a second control terminal CTL2. The switching circuit 401 further includes a first NFET 411a, a second NFET 411b, a first gate biasing resistor 412a, a second gate biasing resistor 412b, a first channel biasing resistor 413, a first body biasing resistor 414a, and a second body biasing resistor 414b. For clarity of the description and figures, the RF switching circuit 401 is illustrated and described as including an “RF input terminal” and “an RF output terminal.” However, persons having ordinary skill in the art will appreciate that the RF switching circuits herein can be used in a variety of applications, and that operation of these terminals as input or output can depend on a variety of factors, such as applied signal and/or biasing conditions. Furthermore, the teachings herein are applicable to configurations in which an RF switching circuit is used bidirectionally, and thus operation of the terminals as input or output can change over time.

The first and second NFETs 411a, 411b are electrically connected in series between the RF input terminal IN and the RF output terminal OUT. For example, the sources of the first and second NFETs 411a, 411b are electrically connected to the RF input terminal IN and the RF output terminal OUT, respectively, and the drains of the first and second NFETs 411a, 411b are electrically connected to one another at a first intermediate node N₁. The first gate biasing resistor 411a is electrically connected between the gate of the first NFET 411a and the first control terminal CTL1, and the second gate biasing resistor 411b is electrically connected between the gate of the second NFET 411b and the first control terminal CTL1. Additionally, the first body biasing resistor 414a is electrically connected between the body of the first NFET 411a and the power low supply voltage V₁, and the second body biasing resistor 414b is electrically connected between the body of the second NFET 411b and the power low supply voltage V₁. The first channel biasing resistor 413 is electrically connected between the second control terminal CTL and the first intermediate node N₁. Although FIG. 4A illustrates using two FETs, the RF switching circuit 401 can be adapted to include additional FETs in the FET series.

Although certain terminals of a FET are referred to as a source or a drain, persons having ordinary skill in the art will appreciate that the source and the drain of a FET can be interchanged. Thus, the teachings herein are applicable to configurations in which the source and drain of a FET are reversed or swapped. As used herein, a source/drain of a FET can refer to one of a source or a drain of the FET, and a drain/source of the FET can refer to the other of the source or drain of the FET.

The switching circuit 401 can receive a first control signal at the first control terminal CTL1 and receive a second control signal at the second control terminal CTL2. In certain configurations, the first and second control signals can have fixed voltage levels when the switching circuit 401 operates in a particular state. In one example, the first and second controls signals can be individually controlled to either a power low supply voltage or a power high supply voltage to control the switching circuit's state. The first and second controls signals can be generated by a switching control circuit (for example, any of the switch control circuits of FIGS. 2A-3C) to control operation of the switching circuit 401 in either an ON state in which the RF input terminal IN and the RF output terminal OUT are electrically coupled to one another or in an OFF state in which the RF input terminal IN and the RF output terminal OUT are electrically decoupling from one another.

When the switching circuit 401 is in the ON state, the first control terminal CTL1 and the second control terminal CTL2 can have voltage levels selected to turn on the first and second NFETs 411a, 411b. For instance, a DC gate-to-source, gate-to-backgate, and gate-to-drain voltage of the first and second NFETs 411a, 411b can be based on a voltage difference between first and second control terminals CTL1, CTL2.

In certain configurations, the second control terminal CTL2 is controlled to ground or 0 V when the switching circuit 401 operates in the ON state. Configuring the switching circuit 401 in this manner can result in the DC bias voltages of the drains and sources of the first and second NFETs 411a, 411b being about equal to 0 V. Thus, the switching circuit 401 can be included in an RF system that operates using 0 V DC bias voltages without needing to include DC blocking capacitors, which can degrade bandwidth. Thus, the RF switching circuit 401 can advantageously be used in wide bandwidth RF systems, such as wide bandwidth digital step attenuators.

When the switching circuit 401 is in the OFF state, the first control terminal CTL1 and the second control terminal CTL2 can have voltage levels selected to turn off the first and second NFETs 411a, 411b. In certain configurations, the first control terminal CTL1 is controlled to a ground or power low supply voltage and the second control terminal CTL2 is controlled to a power high supply voltage when the switching circuit 401 is in the OFF state, thereby controlling the DC bias voltage of the first intermediate node N₁ to a high voltage.

Configuring the switching circuit 401 in this manner can strongly turn off the first and second NFETs 411a, 411b, which can aid in preventing the first and/or second NFETs 411a, 411b from turning on during a portion of the RF signal cycle. For example, in a configuration in which the RF input and output terminals IN, OUT operate with a 0 V DC bias voltage, controlling the second control terminal CTL2 to a high voltage level such as a power high supply voltage can provide margin to prevent the first and/or second NFETs 411a, 411b from turning on during a peak of the RF signal cycle. By biasing the first and second NFETs 411a, 411b with gate-to-source and/or gate-to-drain voltages that are highly negative in the OFF-state, the switching circuit 401 can exhibit higher linearity and/or enhanced power handling capabilities.

As shown in FIG. 4A, the first and second NFETs 411a, 411b receive bias voltages through resistors. By providing the first and second control signals to the NFETs 411a, 411b through resistors or other isolation circuitry, the NFETs' bias voltages can dynamically track changes in the RF signal's voltage amplitude, thereby enhancing performance in the presence of RF signal swing. For example, the NFETs 411a, 411b can include parasitic capacitors that can cause the bodies and gates of the NFETs to track changes to the NFETs' source and drain voltages. For example, the NFETs 411a, 411b can include gate-to-drain and gate-to-source capacitors that can operate to bootstrap the NFETs' gate voltages in response to changes in the source and drain voltages. Similarly, the NFETs 411a, 411b can include body-to-drain and body-to-source capacitors that can operate to bootstrap the NFETs' body voltages in response to changes in the source and drain voltages.

In certain configurations, the first and second gate biasing resistors 412a, 412b, the first channel biasing resistor 413, and the first and second body biasing resistors 414a, 414b can have high resistance values to enhance dynamic tracking of bias voltage levels in the presence of RF signal swing. In one embodiment, the first and second gate biasing resistors 412a, 412b each have a resistance in the range of 1 kΩ to 100 MΩ, the first channel biasing resistor 413 has a resistance in the range of 1 kΩ to 100 MΩ, and the first and second body biasing resistors 414a, 414b each have a resistance in the range of 1 kΩ to 100 MΩ. Although examples of resistance values have been provided, other configurations are possible, such as resistances selected for a particular application, manufacturing process, and/or RF operating frequencies.

Thus, the switching circuit 401 can be biased using resistors such that the voltage of the gate of the first NFET 411a tracks an RF signal voltage at the RF input terminal IN and such that the voltage of the gate of the second NFET 411b tracks an RF signal voltage at the RF output terminal OUT. Thus, the AC voltage of the gate of the first NFET 411a can change with an RF signal component at the RF input terminal IN, and the AC voltage of the gate of the second NFET 411b can change with an RF signal component at the RF output terminal OUT.

In certain configurations, a parasitic gate capacitance of first NFET 411a and a resistance of the first gate biasing resistor 412a can have a time constant that is greater than a time constant of an RF signal received at the RF input IN, and a parasitic gate capacitance of the second NFET 411b and a resistance of the second gate biasing resistor 412b can have a time constant that is greater than the RF signal's time constant. Configuring the switching circuit 401 this manner can aid in maintaining biasing conditions of the first and second NFETs 411a, 411b throughout the duration of an RF signal cycle.

Configuring the first channel biasing resistor 413 to have a relatively large resistance can also help reduce insertion loss of an RF signal propagating through the switching circuit 401. For instance, the impedance of the first channel biasing resistor 413 can be selected be much larger than ON-state impedance of the switching circuit 401, such that an RF signal propagating through the switching circuit 401 is negligibly attenuated.

The first and second body biasing resistors 414a, 414b can help the switching circuit 401 to operate without parasitic forward-biased FET body-to-source and/or body-to-drain diode conduction. For instance, when the first and second body biasing resistors 414a, 414b are configured to have a relatively large resistance, parasitic body-to-source and/or body-to-drain diodes should not become forward-biased during the RF signal cycle. Thus the body voltage of the first NFET 411a can track the first NFET's source voltage, and the body voltage of the second NFET 411b can track the second NFET's source voltage. Accordingly, the AC voltage of the body of the first NFET 411a can change with an RF signal component at the RF input terminal IN, and the AC voltage of the body of the second NFET 411b can change with an RF signal component at the RF output terminal OUT.

In the illustrated configuration, resistors are used to provide DC control signals to NFETs and, as described above, to enhance stability of AC voltages over the RF signal cycle. The resistors can be implemented using passive structures, such as polysilicon, and/or active circuitry such as transistors biased to achieve a desired resistance. Although FIG. 4A illustrates a configuration using resistors, other configurations of isolation circuitry are possible, such as implementations in which inductors and/or a combination of resistors and inductors are used.

The switching circuit 401 can operate as a shunt or series switching circuit in an RF system, including, but not limited to any of the RF systems described herein. For instance, with reference back to the RF switching system 231 of FIG. 2B, the first or series switching circuit 256 and/or the second or shunt switching circuit 266 can be realized using the switching circuit 401.

FIG. 4B is a schematic diagram of an RF switching circuit 402 according to another embodiment. The switching circuit 402 of FIG. 4B is similar to the switching circuit 401 of FIG. 4A, except that the first and second body biasing resistors 414a, 414b are omitted in favor of biasing the bodies of the first and second NFETs 411a, 411b in a different manner. In particular, the body of the first NFET 411a is electrically connected to the source of the first NFET 411a, and the body of the second NFET 411b is electrically connected to the source of the second NFET 411b. [0091] Electrically connecting the source and body of the first NFET 411a to one another and electrically connecting the source and body of the second NFET 411b to one another can also prevent parasitic source-to-body diodes from becoming forward biased during an RF signal cycle. Additional details of the switching circuit 402 can be similar to those described earlier.

FIG. 4C is a schematic diagram of an RF switching circuit 403 according to another embodiment. The switching circuit 403 includes a first NFET 411a, a second NFET 411b, a third NFET 411c, a first gate biasing resistor 412a, a second gate biasing resistor 412b, a third gate biasing resistor 412c, a first channel biasing resistor 413a, a second channel biasing resistor 413b, a first body biasing resistor 414a, a second body biasing resistor 414b a third body biasing resistor 414c, a first explicit gate-to-source capacitor 421a, a second explicit gate-to-source capacitor 421b, a first explicit body-to-source capacitor 422a, and a second explicit body-to-source capacitor 422b.

The switching circuit 403 of FIG. 4C includes three NFETs in series between the RF input terminal IN and the RF output terminal OUT. For example, the first NFET 411a is electrically connected between the RF input terminal IN and the first intermediate node N₁, the third NFET 411c is electrically connected between the first intermediate node N₁ and the second intermediate node N₂, and the second NFET 411b is electrically connected between the second intermediate node N₂ and the RF output terminal OUT. However, the teachings herein are applicable to configurations using more or fewer FETs in series. For example, in one embodiment, a switching circuit includes between 2 and 10 FETs in series.

The first to third NFETs 411a-411c are biased using resistors in a manner similar to that shown in FIG. 4A. For example, the first to third gate biasing resistors 412a-412c are electrically connected between the first control terminal CTL1 and the gates of the first to third NFETs 411a-411c, respectively. Additionally, the first to third body biasing resistors 414a-414c are electrically connected between the power low supply voltage V₁ and the bodies of the first to third NFETs 411a-411c, respectively. Furthermore, the first and second channel biasing resistors 413a, 413b are electrically connected between the second control terminal CTL2 and the first and second intermediate nodes N₁, N₂, respectively.

The switching circuit 403 of FIG. 4C can receive first and second control signals on the first and second control terminals CTL1, CTL2, respectively, and the first and second controls signals can turn on or off the switching circuit 403 in a manner similar to that described earlier.

In contrast to the switching circuit 401 of FIG. 4A, the switching circuit 403 of FIG. 4C further includes explicit bootstrap capacitors, which can help the gate and body voltages of the first and second NFETs 411a, 411b track changes in RF signal amplitude at the RF input terminal IN and the RF output terminal OUT. Configuring the switching circuit 403 in this manner can help enhance performance in the presence of RF signal swing by maintaining a relatively constant gate-to-source voltages during an RF signal cycle and/or by maintaining parasitic body diodes turned off. Although including bootstrapping capacitors can enhance tracking of bias voltages in the presence of RF signal swing, bootstrapping capacitors may also degrade high-frequency performance and thus are not included in certain embodiments.

As shown in FIG. 4C, the first gate-to-source capacitor 421a is electrically connected between the gate and source of the first NFET 411a, and the second gate-to-source capacitor 421b is electrically connected between the gate and source of the second NFET 411b. Additionally, the first body-to-source capacitor 422a is electrically connected between the body and source of the first NFET 411a, and the second body-to-source capacitor 422b is electrically connected between the gate and body of the second NFET 411b. The gate-to-source capacitors 421a,421b and the body-to-source capacitors 422a,422b are explicit capacitive structures, rather than merely parasitic capacitances inherent to the NFETs. Although FIG. 4C illustrates a configuration including both gate-to-source and body-to-source explicit capacitors, certain configurations can omit all or part of the illustrated capacitors in favor of bootstrapping via parasitic capacitance structures.

Additional details of the switching circuit 403 can be similar to those described earlier.

FIG. 4D is a schematic diagram of an RF switching circuit 404 according to another embodiment. The switching circuit 404 of FIG. 4D is similar to the switching circuit 401 of FIG. 4A, except that the first and second body biasing resistors 414a, 414b are omitted in favor of biasing the bodies of the first and second NFETs 411a, 411b in a manner similar to that shown in FIG. 4B. In particular, the body of the first NFET 411a is electrically connected to the source of the first NFET 411a, and the body of the second NFET 411b is electrically connected to the source of the second NFET 411b. Additionally, in contrast to the switching circuit 403 of FIG. 4C, the switching circuit 404 of FIG. 4D omits the first and second explicit body-to-source capacitors 422a, 422b.

Additional details of the switching circuit 404 can be similar to those described earlier.

FIG. 4E is a schematic diagram of an RF switching circuit 405 according to another embodiment. The RF switching circuit 405 includes a first high threshold NFET 431a, a second high threshold NFET 431b, a first low threshold NFET 432a, a second low threshold NFET 432b, a third low threshold NFET 432c, a first gate biasing resistor 412a, a second gate biasing resistor 412b, a third gate biasing resistor 412c, a fourth gate biasing resistor 412d, a fifth gate biasing resistor 412e, a first channel biasing resistor 413a, a second channel biasing resistor 413b, a third channel biasing resistor 413c, a fourth channel biasing resistor 413d, a first body biasing resistor 414a, a second body biasing resistor 414b, a third body biasing resistor 414c, a fourth body biasing resistor 414d, and a fifth body biasing resistor 414e.

The switching circuit 405 of FIG. 4E includes five NFETs in series between the RF input terminal IN and the RF output terminal OUT. For example, the first high threshold NFET 431a is electrically connected between the RF input terminal IN and the first intermediate node N₁, the first low threshold NFET 432a is electrically connected between the first intermediate node N₁ and the second intermediate node N₂, the second low threshold NFET 432b is electrically connected between the second intermediate node N₂ and the third intermediate node N₃, the third low threshold NFET 432c is electrically connected between the third intermediate node N₃ and the fourth intermediate node N₄, and the second high threshold NFET 431b is electrically connected between the fourth intermediate node N₄ and the RF output terminal OUT. However, the teachings herein are applicable to configurations using more or fewer FETs in series.

In the illustrated configuration, the first and second high threshold NFETs 431a, 431b have a higher threshold voltage than the first to third low threshold NFETs 432a-432c. Certain manufacturing processes can be used to fabricate multiple types of N-channel FETs, including FETs with different threshold voltages. For a given gate-to-source bias voltage, a high threshold FET can have a higher ON-state resistance relative to a low threshold FET. However, the high threshold FET can also provide lower leakage/higher OFF-state resistance and can have a higher tolerance to overvoltage conditions. For instance, the high threshold FETs may be rated with higher maximum gate-to-source and/or gate-to-drain operating voltages.

The high threshold NFETs 431a, 431b and low threshold NFETs 432a-432c are biased using resistors in a manner similar to that shown in FIG. 4A. For example, the first and second gate biasing resistors 412a, 412b are electrically connected between the first control terminal CTL1 and the gates of the first and second high threshold NFETs 431a, 431b, respectively. Additionally, the third to fifth gate biasing resistors 412c-412e are electrically connected between the first control terminal CTL1 and the gates of the first to third low threshold NFETs 432a-432c, respectively. Furthermore, the first and second body biasing resistors 414a, 414b are electrically connected between the power low supply voltage V₁ and the bodies of the first and second high threshold NFETs 431a, 431b, respectively. Additionally, the third to fifth body biasing resistors 414c-414e are electrically connected between the power low supply voltage V₁ and the bodies of the first to third low threshold NFETs 432a-432c, respectively. Furthermore, the first to fourth channel biasing resistors 413a-413d are electrically connected between the second control terminal CTL2 and the first to fourth intermediate nodes N₁-N₄, respectively.

In certain configurations, an RF switching circuit includes a first high threshold FET including a source electrically connected to an input terminal, a second high threshold FET including a source electrically connected to an output terminal, and one or more low threshold FETs electrically connected in series between the drain of the first high threshold FET and the drain of the second high threshold FET. For example, FIG. 4E illustrates an example of such a configuration using two high threshold NFETs and three low threshold NFETs.

Including high threshold FETs at the ends of the FET series can further aid in mitigating nonlinearities due to variations in FET process parameters such as threshold voltage and on-resistance. Using FETs with higher threshold can further enhance the off-state resistance by virtue of increased threshold voltage.

Additional details of the switching circuit 405 can be similar to those described earlier.

FIG. 4F is a schematic diagram of an RF switching circuit 406 according to another embodiment. The switching circuit 406 of FIG. 4F is similar to the switching circuit 405 of FIG. 4E, except that the first and second body biasing resistors 414a, 414b are omitted in favor of biasing the bodies of the first and second high threshold NFETs 431a, 431b in a different manner. In particular, the body of the first high threshold NFET 431a is electrically connected to the source of the first high threshold NFET 431a, and the body of the second high threshold NFET 431b is electrically connected to the source of the second high threshold NFET 431b. In the illustrated configuration, the first and second body biasing resistors 414a, 414b are omitted.

Additional details of the switching circuit 406 can be similar to those described earlier.

### Applications

Devices employing the above described RF switching circuits can be implemented into various electronic devices. Examples of the electronic devices can include, but are not limited to, consumer electronic products, parts of the consumer electronic products, electronic test equipment, etc. Examples of the electronic devices can also include circuits of optical networks or other communication networks. The consumer electronic products can include, but are not limited to, an automobile, a camcorder, a camera, a digital camera, a portable memory chip, a washer, a dryer, a washer/dryer, a copier, a facsimile machine, a scanner, a multifunctional peripheral device, etc. Further, the electronic device can include unfinished products, including those for industrial, medical and automotive applications.

The foregoing description and claims may refer to elements or features as being “connected” or “coupled” together. As used herein, unless expressly stated otherwise, “connected” means that one element/feature is directly or indirectly connected to another element/feature, and not necessarily mechanically. Likewise, unless expressly stated otherwise, “coupled” means that one element/feature is directly or indirectly coupled to another element/feature, and not necessarily mechanically. Thus, although the various schematics shown in the figures depict example arrangements of elements and components, additional intervening elements, devices, features, or components may be present in an actual embodiment (assuming that the functionality of the depicted circuits is not adversely affected).

Although this invention has been described in terms of certain embodiments, other embodiments that are apparent to those of ordinary skill in the art, including embodiments that do not provide all of the features and advantages set forth herein, are also within the scope of this invention. Moreover, the various embodiments described above can be combined to provide further embodiments. In addition, certain features shown in the context of one embodiment can be incorporated into other embodiments as well. Accordingly, the scope of the present invention is defined only by reference to the appended claims.

What is claimed is:

1. A radio frequency (RF) system comprising:
a first RF switching circuit comprising:
a first terminal;
a second terminal;
a first control terminal configured to receive a first control signal;
a second control terminal configured to receive a second control signal; and
two of more field-effect transistors (FETs) electrically connected in series between the first terminal and the second terminal, wherein the two or more FETs comprise a first FET including a source/drain electrically connected to the first terminal and a second FET including a source/drain electrically connected to the second terminal, wherein a first intermediate node is disposed along a signal path between a drain/source of the first FET and a drain/source of the second FET,
wherein the first control signal is configured to control a DC bias voltage of a gate of the first FET and a DC bias voltage of a gate of the second FET, and wherein the second control signal is configured to control a DC bias voltage of the first intermediate node.

2. The RF system of claim 1, further comprising:
a first channel biasing resistor electrically connected between the first intermediate node and the second control terminal.

3. The RF system of claim 2, further comprising:
a third FET electrically connected between the drain/source of the first FET and the drain/source of the second FET, wherein a drain/source of the third FET is electrically connected to a second intermediate node different from the first intermediate node; and
a second channel biasing resistor electrically connected between the second intermediate node and the second control terminal.

4. The RF system of claim 1, wherein an AC voltage of the gate of the first FET is configured to change with an RF signal component at the first terminal, and wherein an AC voltage of the gate of the second FET is configured to change with an RF signal component at the second terminal.

5. The RF system of claim 4, further comprising:
a first bootstrap capacitor electrically connected between the source/drain of the first FET and the gate of the first FET; and
a second bootstrap capacitor electrically connected between the source/drain of the second FET and the gate of the second FET.

6. The RF system of claim 4, wherein an AC voltage of a body of the first FET is configured to change with the RF signal component at the first terminal, and wherein an AC voltage of a body of the second FET is configured to change with the RF signal component at the second terminal.

7. The RF system of claim 6, further comprising:
a third bootstrap capacitor electrically connected between the source/drain of the first FET and the body of the first FET; and
a fourth bootstrap capacitor electrically connected between the source/drain of the second FET and the body of the second FET.

8. The RF system of claim 6, wherein the body of the first FET is electrically connected to the source/drain of the first FET, and wherein the body of the second FET is electrically connected to the source/drain of the second FET.

9. The RF system of claim 1, further comprising:
a first gate biasing resistor electrically connected between the gate of the first FET and the first control terminal, wherein the first gate biasing resistor has a resistance between 1 kΩ to 100 MΩ; and
a second gate biasing resistor electrically connected between the gate of the second FET and the first control terminal, wherein the second gate biasing resistor has a resistance between 1 kΩ to 100 MΩ.

10. The RF system of claim 9, further comprising:
a first body biasing resistor electrically connected between the body of the first FET and a first voltage, wherein the first body biasing resistor has a resistance between 1 kΩ to 100 MΩ; and
a second body biasing resistor electrically connected between the body of the second FET and the first voltage, wherein the second body biasing resistor has a resistance between 1 kΩ to 100 MΩ.

11. The RF system of claim 1, wherein the first FET comprises a first high threshold FET and the second FET comprises a second high threshold FET, wherein the two or more FETs further comprises one or more low threshold FETs electrically connected in series between the drain/source of the first high threshold FET and the drain/source of the second high threshold FET.

12. The RF system of claim 1, further comprising:
a control circuit configured to generate a plurality of control signals including the first control signal and the second control signal, wherein the control circuit is configured to control the first RF switching circuit to an OFF state by controlling the first control signal to a first voltage and by controlling the second control signal to a second voltage, and wherein the control circuit is configured to control the first RF switching circuit to an ON state by controlling the first control signal to the second voltage and by controlling the first control signal to the first voltage.

13. The RF system of claim 12, wherein the first FET and the second FET comprise N-channel FETs (NFETs), wherein the first voltage comprises a ground voltage, and wherein the second voltage is greater than the ground voltage.

14. The RF system of claim 13, further comprising an RF circuit including an output having a DC bias voltage about equal to the ground voltage, wherein the output of the RF circuit electrically is connected to the first terminal without a DC blocking capacitor.

15. The RF system of claim 1, further comprising:
a second RF switching circuit including a first terminal electrically connected to the first terminal of the first RF switching circuit, wherein the first RF switching circuit is configured as one of a series switch or a shunt switch and the second RF switching circuit is configured as the other of the series switch or the shunt switch.

16. The RF system of claim 1, further comprising:
a digital step attenuator (DSA) comprising a plurality of attenuation stages, wherein a first attenuation stage of the plurality of attenuation stages comprises the first RF switching circuit.

17. A method of radio frequency (RF) switching, the method comprising:
receiving a first control signal and a second control signal as inputs to an RF switching circuit, the RF switching circuit comprising two or more field-effect transistors (FETs) electrically connected in series between a first terminal and a second terminal;
controlling a DC bias voltage of a gate of a first FET of the two or more FETs using the first control signal, wherein a source/drain of the first FET is electrically connected to the first terminal;
controlling a DC bias voltage of a gate of a second FET of the two or more FETs using the first control signal, wherein a source/drain of the second FET is electrically connected to the second terminal; and
controlling a DC bias voltage of a first intermediate node using the second control signal, wherein the first intermediate node is disposed along a signal path between a drain/source of the first FET and a drain/source of the second FET.

18. The method of claim 17, further comprising:
receiving an input signal at the first terminal; and
controlling an AC voltage of the gate of the first FET using an RF signal component of the input signal.

19. The method of claim 18, further comprising:
bootstrapping the gate and the source/drain of the first FET using a first bootstrapping capacitor; and
bootstrapping the gate and the source/drain of the second FET using a second bootstrapping capacitor.

20. The method of claim 18, further comprising:
controlling a DC bias voltage of the first terminal to a ground voltage; and
controlling the first control signal to the ground voltage; and
controlling the second control signal to a voltage greater than the ground voltage to maintain the RF switching circuit off during an RF signal cycle of the input signal.

21. A digital step attenuator comprising:
an attenuation control circuit configured to generate a plurality of control signals including a first control signal and a second control signal;
a plurality of attenuation stages comprising a first attenuation stage, wherein the first attenuation stage comprises a first RF switching circuit comprising:
a first terminal;
a second terminal;
a first control terminal configured to receive the first control signal;
a second control terminal configured to receive the second control signal; and
two of more field-effect transistors (FETs) electrically connected in series between the first terminal and the second terminal, wherein the two or more FETs comprise a first FET including a source/drain electrically connected to the first terminal and a second FET including a source/drain electrically connected to the second terminal, wherein a first intermediate node is disposed along a signal path between a drain/source of the first FET and a drain/source of the second FET,
wherein the first control signal is configured to control a DC bias voltage of a gate of the first FET and a DC bias voltage of a gate of the second FET, and wherein the second control signal is configured to control a DC bias voltage of the first intermediate node.

22. The digital step attenuator of claim 21, wherein the first attenuation stage further comprises:
an attenuation circuit including a first terminal electrically connected to an input of the first attenuation stage and a second terminal electrically connected to an output of the first attenuation stage, wherein the first terminal of the first RF switching circuit is electrically connected to the first terminal and the second terminal of the first RF switching circuit is electrically connected to the second terminal.

23. The digital step attenuator of claim 21, wherein the first attenuation stage further comprises:
an attenuation circuit including a first terminal electrically connected to an input of the first attenuation stage, a second terminal electrically connected to output of the first attenuation stage, and a third terminal, wherein the first terminal of the first RF switching circuit is electrically connected to the third terminal and the second terminal of the first RF switching circuit is electrically connected to a first voltage.

24. The digital step attenuator of claim 23, wherein the attenuation circuit comprises one of a T attenuator, a bridged-T attenuator, or a pi attenuator.
